(19) United States
(12) Patent Application Publication
(10) Pub. No.: US 2003/0060055 A1
(43) Pub. Date: Mar. 27, 2003

(54) Resist pattern, a method for fabricating a resist pattern, a method for patterning a thin film and a method for manufacturing a micro device

(75) Inventor: Akifumi Kamijima, Chuo-Ku (JP)

Correspondence Address: OLIFF & BERRIDGE, PLC, P.O. BOX 19928, ALEXANDRIA, VA, 22320, US

(73) Assignee: TDK CORPORATION, Tokyo (JP)

(21) Appl. No.: 09/964,433

(22) Filed: Sep. 28, 2001

(30) Foreign Application Priority Data
Oct. 5, 2000 (JP) 2000-305,624

(51) Int. Cl. H01L 21/302; H01L 21/461

(52) U.S. Cl. 438/725; 438/708

(57) ABSTRACT

A resist pattern according to the present invention is constructed of a trapezoid main body and a supplemental body to support on a given base material the main body which is narrowed, as compared with the main body. Then, the upper base “a” and the lower base “b” of the main body satisfy the relation of “b>a” in their widths, and the angle 0 between the lower base “b” and the side surface wall of the main body is set to be smaller than 90 degrees.

### BACKGROUND OF THE INVENTION

1. Field of the Invention

This invention relates to a resist pattern, a method for fabricating a resist pattern, a method for patterning a thin film and a method for manufacturing a micro device.

2. Related Art Statement

Thin film-patterning is performed by using a milling method, a lift-off method or a combination method of milling and lift-off. Then, a resist pattern for the thin film-patterning is normally formed as shown in FIGS. 1 and 2.

In FIG. 1, the resist pattern is formed in a T-shape, and constructed of a main body 1 and a supplemental body 2 to support the main body 1 which is narrowed as compared with the main body 1. In FIG. 2, the resist pattern is formed in a polygonal shape, and constructed of a main body 11 and a supplemental body 2 to support the main body 11 which is narrowed as compared with the main body 1. In the resist patterns depicted in FIGS. 1 and 2, the upper base widths “W1” and “W3” and the lower base widths “W2” and “W4” satisfy the relations of W1≧W2 and W3≧W4.

In the case that a thin film is patterned via such a resist pattern by a milling method or the like, the width of the thin film is defined by the upper base width of the main body of the resist pattern because the upper base width of the main body is larger or equal to the lower base width thereof.

Moreover, in the case that a thin film is patterned via such a resist pattern by a lift-off method, a large amount of the patterned wastage is stuck on the lower portions of the main body of the resist pattern, and thus, the edge portions of the thin film results in being formed steeply.

In the case that the thin film is patterned by a milling method, the incident angle of the milling particles is more enlarged due to the radiation angle of the milling particles and the configuration of the main body of the resist pattern. Therefore, a minute patterned thin film can not be obtained by the milling method.

Moreover, as mentioned above, since the width of the patterned thin film is determined by the upper base width of the main body of the resist pattern due to the configuration of the resist pattern, the width of the patterned thin film is influenced by the fluctuation of the radiation angle of the milling particles. As a result, the precise thin film patterning can be performed.

In the lift-off method, a thicker thin film having its steep edge portions to be patterned may be contacted to the resist pattern, and thus, some burr may be created.

In the case that a thin film is patterned via the above-mentioned resist pattern by a combination method of milling and lift-off, a large amount of patterned wastage is stuck on the edge portions of a thin film to be milled via the lower portions of the main body of the resist pattern. Therefore, the uniform thin film patterning can not be performed.

### SUMMARY OF THE INVENTION

It is an object of the present invention to provide, in thin film patterning by a milling method or the like, a resist pattern and a method for fabricating a resist pattern to fabricate a uniform and minute patterned thin film.

Also, it is an object of the present invention to provide a method for patterning a thin film uniformly and minutely, and a method for manufacturing a micro device by using the patterning method.

In order to achieve the above object, this invention relates to a resist pattern including a trapezoid main body and a supplemental body to support the main body which is narrowed as compared with the main body, wherein the upper base “a” and the lower base “b” satisfy the relation of “b>a” in their widths, and the angle θ between the lower base “b” and the side surface wall of the main body is set to be smaller than 90 degrees.

In a preferred embodiment of the present invention, the angle θ is set to 60 degrees or over. In another preferred embodiment, the angle θ is set to 87 degrees or below.

The inventors had been intensely studied to iron out the above-mentioned problems in the thin film patterning using a milling method, a lift-off method or a combination method of milling and lift-off. As a result, they found out these problems can be solved by using a resist pattern depicted in FIG. 3 or 4, according to the present invention.

In FIG. 3, the resist pattern includes a trapezoid main body 31 and a supplemental body 32 to support the main body 31 which is narrowed as compared with the main body 31. Then, the upper base “a1” and the lower base “b1” satisfies the relation of “b1>a1” in their widths, and the angle θ1 between the lower base “b1” and the side surface wall 31A of the main body 31 is set to be smaller than 90 degrees.

Similarly, in FIG. 4, the resist pattern includes a trapezoid main body 41 and a supplemental body 42 to support the main body 41 which is narrowed as compared with the main body 41. Then, the upper base “a2” and the lower base “b2” satisfies the relation of “b2>a2” in their widths, and the angle θ2 between the lower base “b2” and the side surface wall 41A of the main body 41 is set to be smaller than 90 degrees.

FIGS. 5 and 6 show milled thin films via a resist pattern according to the present invention and a conventional resist pattern, respectively.

The resist pattern according to the present invention has, as shown in FIGS. 3 and 4, a trapezoid shape and thus, its enlarged bottom portion. Therefore, in the thin film patterning using a milling method, the width of the thus obtained patterned thin film is determined by the width of the bottom portion of the resist pattern. If the width of the bottom portion is set to a given value, a thin film 20 can be milled and patterned (in a width of “r”) minutely corresponding to the bottom portion width, irrespective of the irradiation angle of the milling particles.

On the other hand, the conventional resist pattern has, as shown in FIGS. 1 and 2, a reversed trapezoid shape, and thus, its enlarged top portion. Therefore, in the thin film patterning using a milling method, the width of the thus obtained patterned thin film is determined by the width of the top portion of the resist pattern. Therefore, the dispersion effect of the milling particles is increased, and thus, the thin film 20 is milled and patterned (in a width “R”>“r”) widely. Moreover, due to the large dispersion of the milling particles, the precise thin film patterning can not be performed.

FIGS. 7 and 8 show lifted-off thin films via a resist pattern according to the present invention and a conventional resist pattern, respectively. Since the resist pattern according to the present invention has a reversed trapezoid shape, and thus, its wider bottom portion, a thin film 21 to be patterned is partially deposited on the side surface wall of the resist pattern. Therefore, in patterning for the thin film 21, the resist pattern including the deposited portion of the thin film 21 is employed as a mask.

Therefore, the patterned wastage is not deposited below the resist pattern. As a result, as shown in FIG. 7, the distance “D” between the thin film 21 to be patterned and the resist pattern is relatively enlarged, and thus, the thin film 21 is not almost contacted to the resist pattern. Accordingly, the burr creation can be prevented.

On the other hand, as shown in FIG. 8, since the upper base of the conventional resist pattern is relatively enlarged, a large amount of patterned wastage is stuck below the resist pattern. As a result, the thin film 21 is deposited thicker, and has its steep edge portions, resulting in the decrease of the distance “d” between the edge portions of the thin film 21 and the resist pattern. Therefore, the thin film 21 to be patterned may be contacted to the resist pattern, and thus, some burr may be created.

FIGS. 9 and 10 show patterned films via a resist pattern according to the present invention and a conventional resist pattern, respectively, through a combination method of milling method and lift-off method.

As shown in FIG. 9, using the resist pattern according to the present invention, only a small amount of deposited wastage in forming a thin film 23 to be patterned is stuck below the resist pattern. Therefore, the thus obtained thin film 23 is not almost hung over a pre-patterned thin film 22. As a result, a uniform patterned thin film can be made.

On the other hand, as shown in FIG. 10, using the conventional resist pattern, a large amount of deposited wastage in forming the thin film 23 is stuck below the resist pattern. Therefore, the thus obtained thin film 23 is substantially hung over the pre-patterned thin film 22. As a result, a uniform patterned thin film can not be made.

The above-mentioned resist pattern according to the present invention may be made by a fabricating method according to the present invention as follows.

A first fabricating method of a resist pattern includes the steps of forming a photoresist layer on a given base material, and exposing the photoresist layer so that the focal point of the exposing light is shifted from on the surface of the resist layer.

In a preferred embodiment of the first fabricating method, in the exposing treatment for the photoresist layer, the focal point is set to a position above the photoresist layer. In another preferred embodiment of the first fabricating method, the focal point is set to a position as high as 0.1-1.0 times of the thickness of the photoresist layer from on the surface of the photoresist layer.

A second fabricating method of a resist pattern includes the steps of forming a photoresist layer on a given base material, and exposing and developing the photoresist layer with a developing solution containing an interfacial active agent.

In a preferred embodiment of the second fabricating method, the concentration of the interfacial active agent in the developing solution is set to 0.0001-0.01 wt %.

In a patterning method of a thin film according to the present invention, a thin film is patterned via the above-mentioned resist pattern by a milling method, a lift-off method or a combination method of milling and lift-off.

Then, in a manufacturing method of a micro device according to the present invention, the above-mentioned thin film-patterning method is employed.

Herein, the wording “given base material” means a single substrate or a combination of a substrate and an underlayer for a thin film to be milled or a micro device.

### BRIEF DESCRIPTION OF THE DRAWINGS

For a better understanding of this invention, reference is made to the attached drawings, wherein:

FIG. 1 is a constitutional view showing a conventional resist pattern,

FIG. 2 is a constitutional view showing a conventional resist pattern,

FIG. 3 is a constitutional view showing a resist pattern according to the present invention,

FIG. 4 is a constitutional view showing a resist pattern according to the present invention,

FIG. 5 is an explanatory view showing a milling process for a thin film to be patterned using a resist pattern according to the present invention,

FIG. 6 is an explanatory view showing a milling process for a thin film to be patterned using a conventional resist pattern,

FIG. 7 is an explanatory view showing a lift-off process for a thin film to be patterned using a resist pattern according to the present invention,

FIG. 8 is an explanatory view showing a lift-off process for a thin film to be patterned using a conventional resist pattern,

FIG. 9 is an explanatory view showing a combination method of milling and lift-off for a thin film to be patterned using a resist pattern according to the present invention,

FIG. 10 is an explanatory view showing a combination method of milling and lift-off for a thin film to be patterned using a conventional resist pattern,

FIG. 11 is a graph showing the relation between the angle θ between the lower base and the side surface wall of the main body of a resist pattern and the rising angle of the edge portion of a patterned thin film,

FIG. 12 is a cross sectional view showing a first step of a thin film-patterning method according to the present invention,

FIG. 13 is a cross sectional view showing the next step after the step shown in FIG. 12,

FIG. 14 is a cross sectional view showing the next step after the step shown in FIG. 13,

FIG. 15 is a cross sectional view showing the next step after the step shown in FIG. 14,

FIG. 16 is a cross sectional view showing the next step after the step shown in FIG. 15,

FIG. 17 is a cross sectional view showing the next step after the step shown in FIG. 16,

FIG. 18 is a cross sectional view showing a first step of another thin film-patterning method according to the present invention,

FIG. 19 is a cross sectional view showing the next step after the step shown in FIG. 18,

FIG. 20 is a cross sectional view showing the next step after the step shown in FIG. 19,

FIG. 21 is a cross sectional view showing the next step after the step shown in FIG. 20,

FIG. 22 is a cross sectional view showing the next step after the step shown in FIG. 21,

FIG. 23 is a cross sectional view showing a step of still another thin film-patterning method according to the present invention,

FIG. 24 is a cross sectional view showing the next step after the step shown in FIG. 23,

FIG. 25 is a cross sectional view showing the next step after the step shown in FIG. 24,

FIG. 26 is a cross sectional view showing a manufacturing step of a thin film magnetic head using a resist pattern-fabricating method and a thin film-patterning method according to the present invention,

FIG. 27 is a cross sectional view showing the next step after the step shown in FIG. 26,

FIG. 28 is a cross sectional view showing the next step after the step shown in FIG. 27, and

FIG. 29 is a cross sectional view showing the next step after the step shown in FIG. 28.

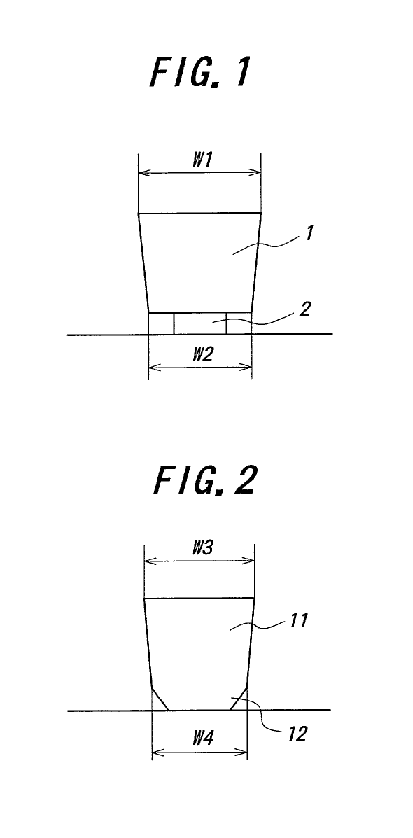

### DETAILED DESCRIPTION OF PREFERRED EMBODIMENTS

This invention will be explained in detail, with reference to the attaching drawings, hereinafter.

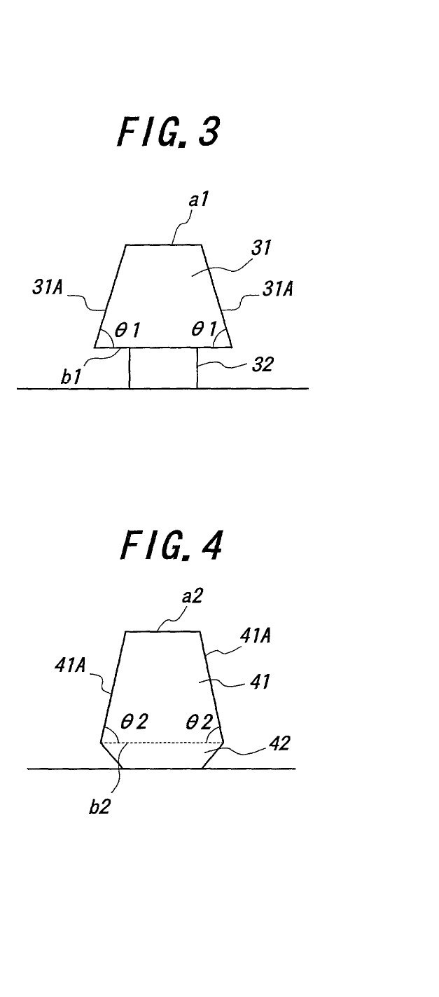

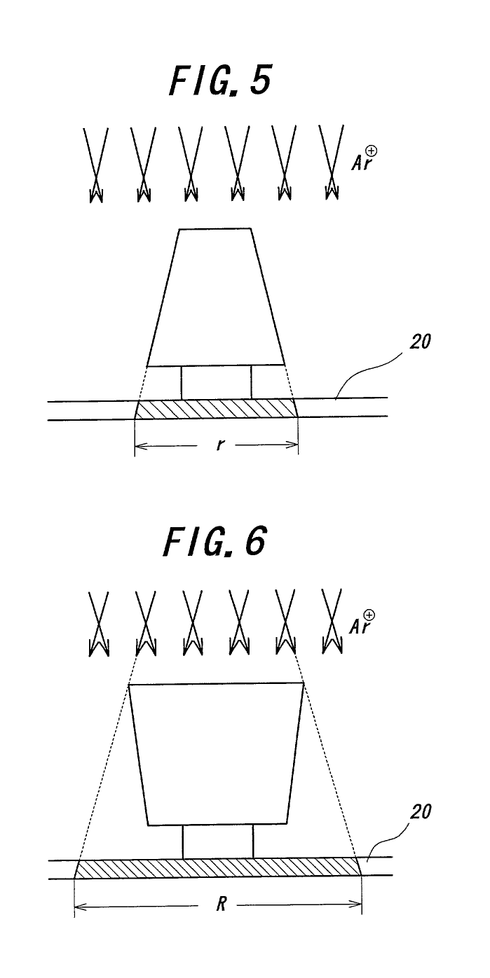

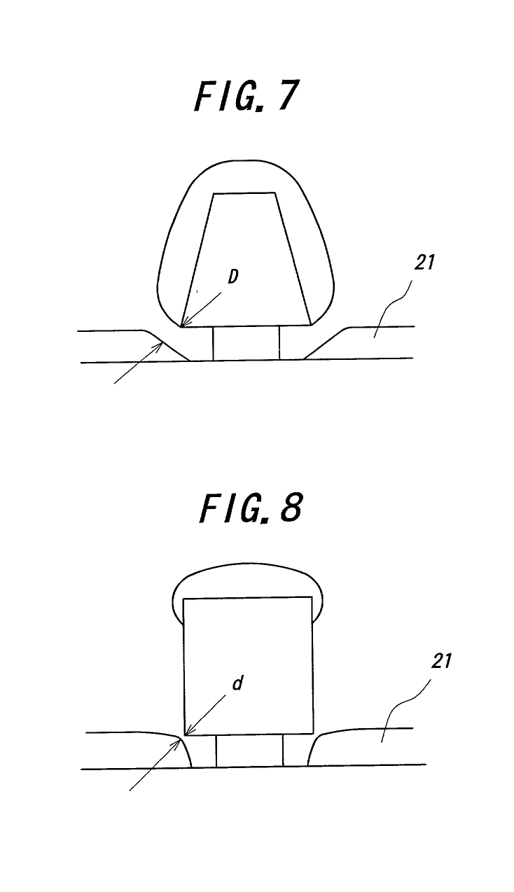

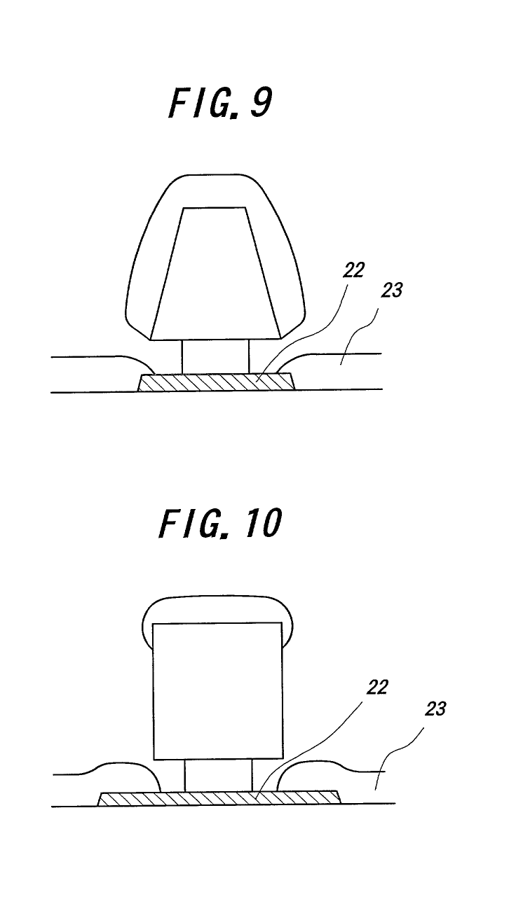

In a resist pattern according to the present invention, it is required that the angle θ between the lower base and the side surface wall of the main body, for example, the angles θ1 and θ2 as shown in FIGS. 3 and 4 are set to be smaller than 90 degrees. Thereby, the object of the present invention can be realized more effectively. Moreover, it is desired that the angle θ is set to 87 degrees or below, particularly 85 degrees or below. In this case, a thin film can be acutely patterned, and thus, a patterned thin film having its steep edge portions.

Also, it is desired that the angle θ is set to 60 degrees or over, particularly 70 degrees or over. In this case, the thin film can be more acutely patterned, and thus, the edge portions of the thus obtained patterned thin film becomes steeper.

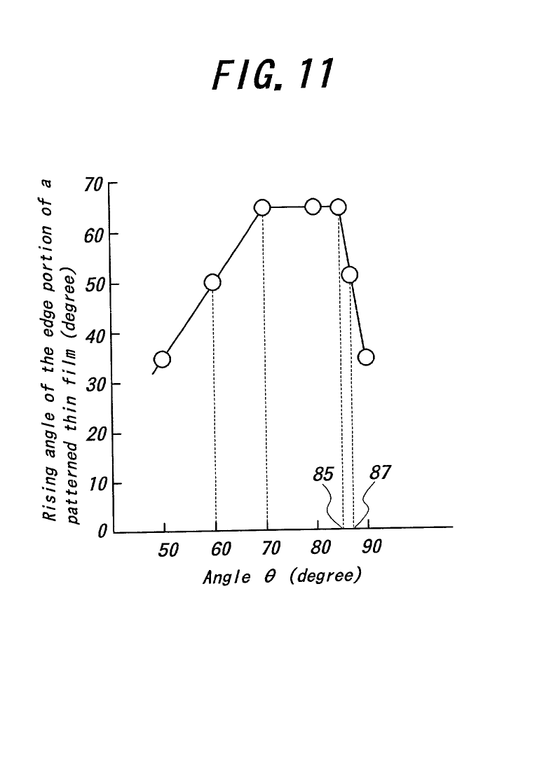

FIG. 11 is a graph showing the relation between the angle θ and the rising angle of the edge portion of the patterned thin film. From FIG. 11, it is turned out that the rising angle of the edge portion becomes steep beyond 50 degrees at an angle θ range of 60-87 degrees, and then, becomes steeper beyond 60 degrees at an angle θ range of 70-85 degrees.

The above-mentioned resist pattern may be made by a first fabricating method according to the present invention. In this case, the photoresist layer to constitute the resist pattern is exposed so that the focal point is shifted from on the surface of the photoresist layer. Preferably, the focal point is set to a given position above the surface of the photoresist layer. Thereby, the resist pattern can be easily made by a normal exposing treatment without another complicate optical system and the subsequent developing treatment.

In the case of setting the focal point to a position above the photoresist layer, it is desired that the focal point is set a position as high as 0.1-1.0 times, particularly 0.1-0.5 times of the thickness of the photoresist layer from on the surface of the photoresist layer. Thereby, the angle θ between the lower base and the side surface wall of the main body of the resist pattern can be easily set to the above-mentioned preferable angle range.

The above-mentioned resist pattern according to the present invention may be made by a second fabricating method according to the present invention. In this case, the photoresist layer to constitute the resist pattern is normally exposed and then, developed with a developing solution containing an interfacial active agent.

The concentration of the interfacial active agent in the developing solution depends on the kinds of the developing base solution and the interfacial active agent. Preferably, the concentration is set to 0.0001-0.01 wt %, particularly 0.0005-0.005 wt %. Thereby, the angle θ between the lower base and the side surface wall of the main body of the resist pattern can be easily set to the above preferable angle range.

As the interfacial active agent, commercially available one such as nonionic polyether-based interfacial active agent may be used. As the developing base solution, commercially available one such as 2.38%-TMAH water solution may be used.

According to the first and the second fabricating methods of the present invention, the resist pattern of the present invention can be easily made. Moreover, for fabricating such a resist pattern having a narrowed supplemental body for a main body as shown in FIGS. 3 and 4, it is desired that a two-layered structure of a polymethylglutarimide layer (PMGI layer) and a photoresist layer formed on the PMGI layer is fabricated on a given base material, and then, the above-mentioned fabricating method is performed to the photoresist layer, to form a so-called Bi-layered type resist pattern.

In this case, the photoresist layer is exposed and developed, and then, the PMGI layer is partially removed with an alkaline water solution, according to the above fabricating method of the present invention.

Instead of fabricating the Bi-layered type resist pattern, a so-called MG type photoresist made of a novolac type positive photoresist containing a phenol dissolution accelerator may be employed. In this case too, the resist pattern having the narrowed supplemental body can be easily fabricated.

As the phenol dissolution accelerator to be used in the MG type photoresist, low nucleic substance having phenolhydroxyl group and 2-5 benzene rings may be used, as described in Japanese Patent No. 2973874. Concretely, the substance is designated by the following structural formulas (1) and (2)

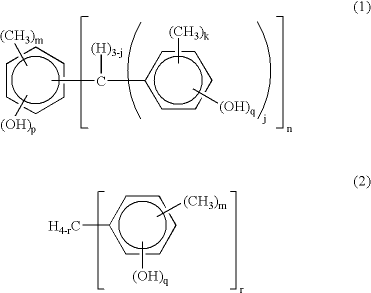

(j: 1 or 2, k,m,p: 0-3, n: 1-4, q: 1-3, r: 2 or 3, m+p+n≦6, k+q≦5)

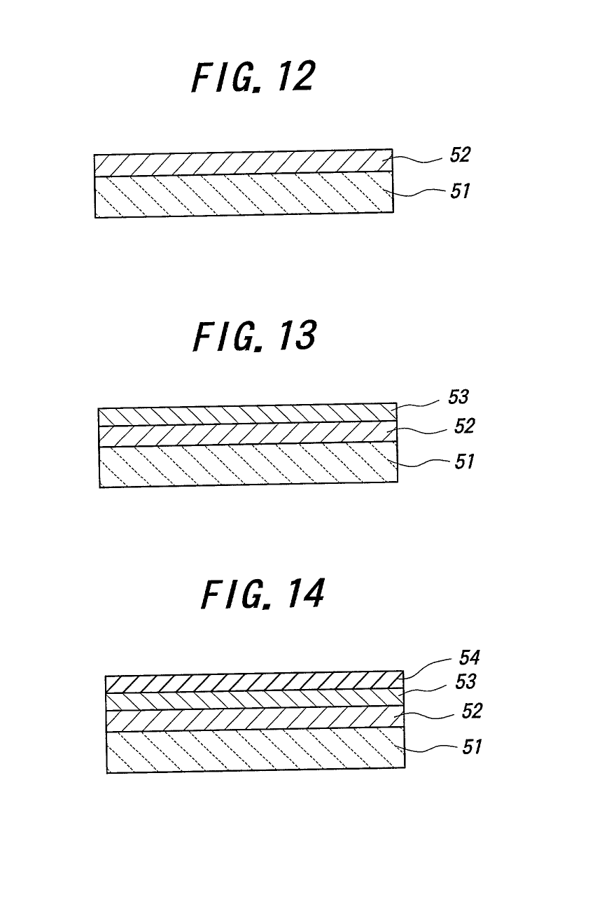

Next, a thin film-patterning method using the above-mentioned resist pattern will be explained. FIGS. 12-17 are cross sectional views showing patterning steps for a thin film using a Bi-layered type resist pattern.

First of all, as shown in FIG. 12, a thin film 52 to be milled is formed on a substrate 51 by sputtering method or the like. Then, as shown in FIG. 13, a PMGI layer 53 is coated on the thin film 52 to be milled, and heated. Then, as shown in FIG. 14, a photoresist layer 54 of e.g., positive type is formed on the PMGI layer 53, and heated.

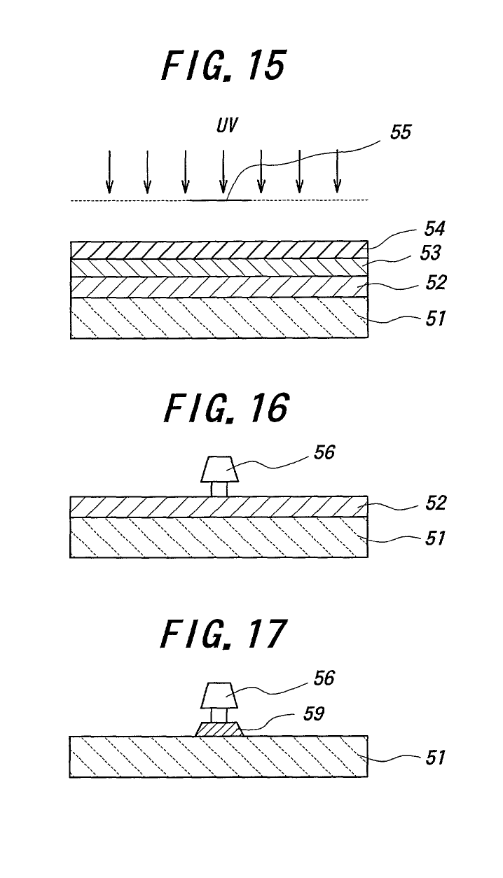

Thereafter, as shown in FIG. 15, the photoresist layer 54 is exposed via a given mask 55 through UV irradiation. According to the first fabricating method of the present invention, the exposing light is irradiated so that the focal point is shifted from on the surface of the photoresist layer 54.

Then, heating treatment as occasion demands and developing treatment are performed for the photoresist layer 54. According to the second fabricating method of the present invention, in the developing treatment, such a developing solution as containing an interfacial active agent by a given amount is used.

Then, the remaining PMGI layer 53 is partially removed with an alkaline water solution to form such a resist pattern 56 as shown in FIG. 16.

Subsequently, the thin film 52 is milled via the resist pattern 56, and patterned minutely to form a minute patterned thin film 59 as shown in FIG. 17. The resist pattern is removed lastly with a solvent.

In the case that a MG type resist pattern employed, and a milling method is employed, the thin film patterning is fundamentally performed by the same manner as shown in FIGS. 12-17.

However, instead of forming the PMGI layer and the positive photoresist layer in FIGS. 13 and 14, the MG type photoresist is coated and formed uniformly. Thereafter, the exposing treatment and the developing treatment are carried out by the same manner as shown in FIGS. 15-17, to fabricate a resist pattern and thus, to pattern the thin film through milling treatment.

Herein, after coating the MG type photoresist and/or in between the exposing treatment and the developing treatment, for facilitating the shift of a dissolution accelerator to the substrate, another heating treatment may be employed.

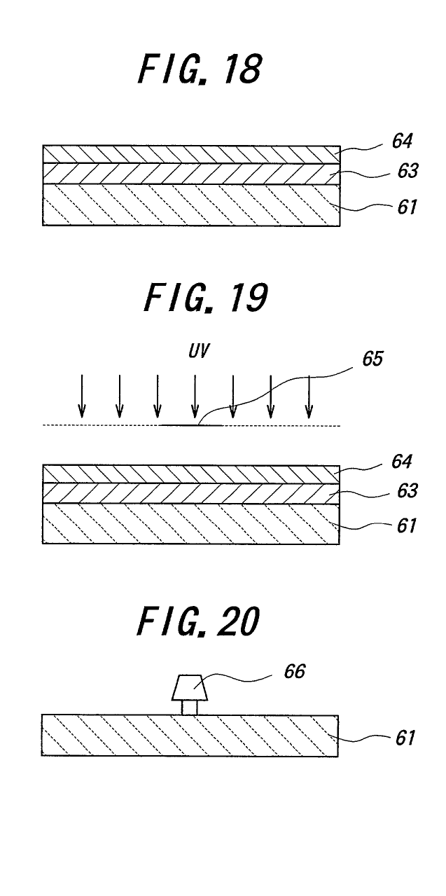

Next, the thin film-patterning method using a Bi-layered type resist pattern and a lift-off method will be explained. FIGS. 18-22 are cross sectional views showing the fabricating steps of the patterning method.

First of all, as shown in FIG. 18, a PMGI layer 63 and a positive photoresist layer 64 are coated on a substrate 61, and heated. Then, as shown in FIG. 19, the photoresist layer 64 is exposed via a given mask 65 through UV irradiation or the like. In the case of using the first fabricating method of a resist pattern according to the present invention, the focal point is shifted from on the surface of the photoresist layer 64.

Then, heating treatment as occasion demands and developing treatment are performed for the photoressist layer 64. In the case of using the second fabricating method of a resist pattern according to the present invention, in the developing treatment, such a developing solution as containing an interfacial active agent by a given amount is used.

Then, the remaining PMGI layer 63 is partially removed with an alkaline water solution to form such a resist pattern 66 as shown in FIG. 20.

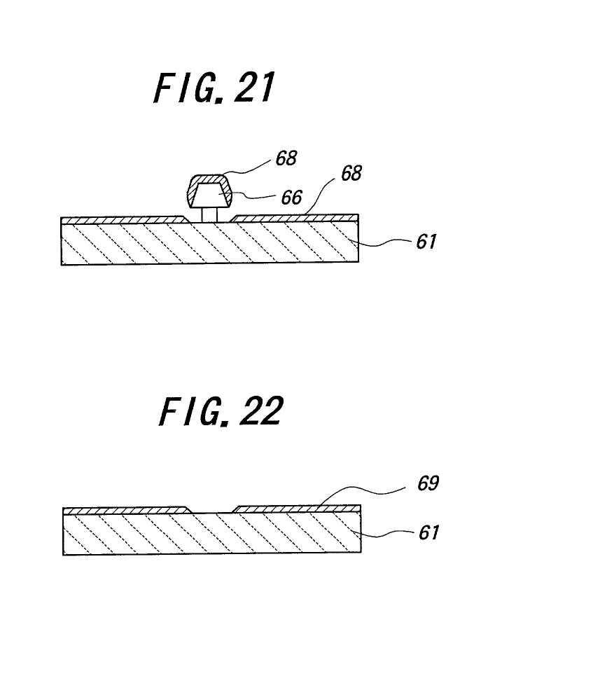

Then, as shown in FIG. 21, a thin film 68 to be patterned is formed on the substrate 61 so as to cover the resist pattern 66. Thereafter, the resist pattern 66 is dissolved and removed with a given organic solvent, to form a patterned thin film 69 as shown in FIG. 22.

In the case of using a MG type resist pattern, instead of forming the PMGI layer and the positive photoresist layer, a MG type photoresist is coated and formed uniformly. Thereafter, such fabricating steps as shown in FIGS. 19-22 are carried out to obtain a patterned thin film.

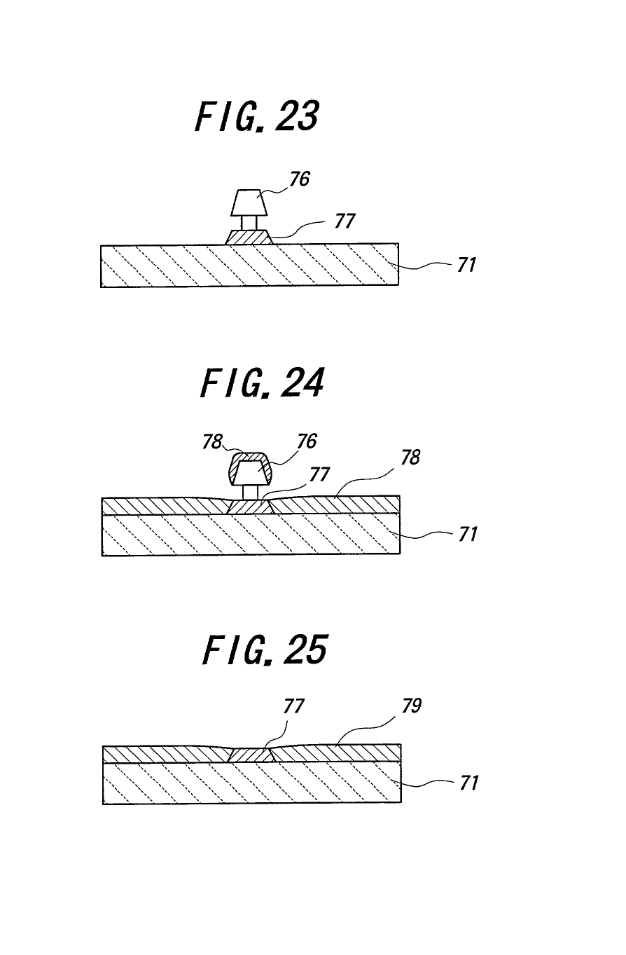

Next, the thin film-patterning method using a Bi-layered type resist pattern and a combination method of milling and lift-off will be explained. FIGS. 23-25 are cross sectional views showing the fabricating method of the patterning method.

First of all, according to the fabricating steps of the thin film-patterning method using the milling method, a pre-patterned thin film 77 and a resist pattern 76 are formed on a substrate 71, as shown in FIG. 23. Then, similar to the fabricating step of the thin film-patterning method using the lift-off method, a thin film 78 to be patterned is formed on the substrate 71 so as to cover the resist pattern 76. Then, the resist pattern 76 is dissolved and removed, to form a patterned thin film 79, as shown in FIG. 25.

Instead of using the Bi-layered type resist pattern, a MG type resist pattern may be employed in the above thin film-patterning method.

The resist pattern-fabricating method and the thin film-patterning method according to the present invention may be preferably employed for a micro device such as a semiconductor laser, an optical isolator, a micro actuator and a thin film magnetic head. particularly, these methods are preferably employed for a thin film magnetic head requiring miniaturization in light of high density recording/reproducing.

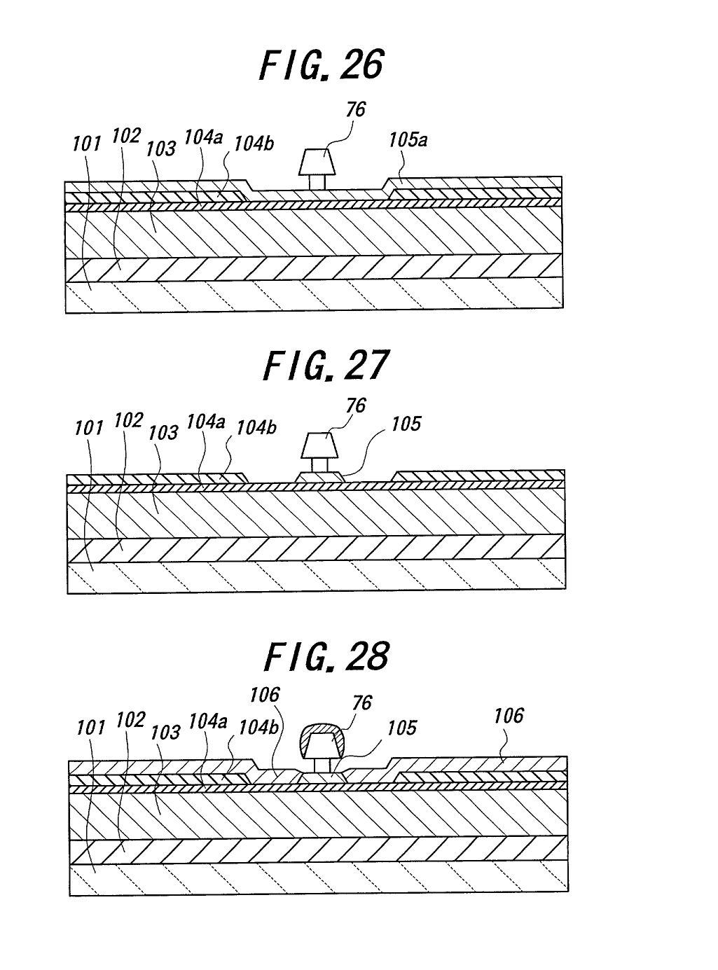

Next, a fabrication process of a giant magnetophotoresistive effective element (hereinafter, often abbreviated as “GMR element”) of a thin film magnetic head using the resist pattern-fabricating method and the thin film-patterning method will be described. FIGS. 26-29 are fabrication process charts of the GMR element, and show the cross sectional views, taken on the line parallel to the ABS of the magnetic pole portion (parallel direction to the medium opposing surface).

First of all, as shown in FIG. 26, an insulating layer 102 is formed of alumina (Al₂O₃), etc., on a substrate 101 made of AlTiC (Al₂O₃ TiC). Then, a bottom shielding layer 103 for the playback head is formed of a magnetic material on the insulating layer 102. Then, a first shielding gap thin film 104a is formed of an insulating material such as alumina on the bottom shielding layer 103.

Then, a second shielding gap thin film 104b is formed of an insulating material such as alumina, except the area for the GMR element to be formed, on the first shielding gap thin film 104a. Then, a magnetic layer 105a to be fabricated as the GMR element is formed on the second shielding gap thin film 104b. Subsequently, a resist pattern 76 is formed on the area for the GMR element to be formed according to the fabrication process as shown in FIGS. 12-17.

Then, as shown in FIG. 27, the magnetic layer 105a is selectively etched by ion milling using the resist pattern 76 as a mask, to form the GMR element 105. Next, as shown in FIG. 28, a pair of leading layers 106 to be electrically connected to the GMR element are formed entirely on the first shielding gas thin film 104a, the second shielding gap thin film 104 and the resist pattern 76, according to the fabricating step as shown in FIG. 24. Then, the resist pattern 76 is removed.

That is, in the fabricating steps shown in FIGS. 26-28, a milling method and a lift-off method are employed to fabricate the patterned thin film constructed of the GMR element 105 and the pair of leading layers 106.

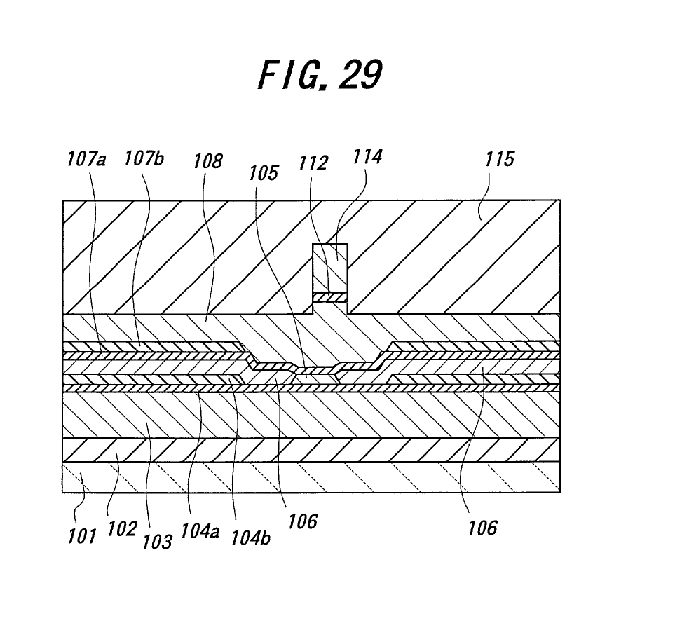

Then, as shown in FIG. 29, a third shielding gap thin film 107a is formed of an insulating material such as alumina on the shielding gap thin films 104a, 104b, the GMR element 105 and the leading layers 106, and the GMR element 105 is embedded in between the shielding gap thin films 104a and 107a. Subsequently, except the nearby area to the GMR element 105, a fourth shielding gap thin film 107b is formed of an insulating material such as alumina on the third shielding gap thin film 107a.

Thereafter, a bottom magnetic layer 108 as a top shielding layer, a write gap layer 112, a top magnetic layer 114, not shown a thin film coil and a protective layer 115 are formed in turn, and the ABS is polished, thereby to complete a thin film magnetic head. In FIG. 29, the side surfaces of the top shielding layer is self-aligned to construct the trim structure.

This invention has been described in detail with reference to the above preferred concrete embodiments, but it is obvious for the ordinary person skilled in the art that various modifications can be made in its configuration and detail without departing from the scope of this invention.

For example, in the above resist pattern-fabricating method, the first fabricating method including the focal point shifting process at the exposing treatment and the second fabricating method including the developing treatment using the developing solution containing an interfacial active agent are employed separately, but there fabricating method may be combined.

As mentioned above, according to the resist pattern and the resist pattern-fabricating method of the present invention, a thin film patterning can be performed precisely and minutely through a milling method. Moreover, no burr is created at the thin film patterning using a lift-off method.

Furthermore, at the thin film patterning using a combination method of milling and lift-off, a thin film to be patterned is not almost hung over a milled thin film located below a resist pattern formed by a milling method. Therefore, a uniform patterned thin film can be formed.

What is claimed is:

1. A resist pattern including a trapezoid main body and a supplemental body to support the main body which is narrowed as compared with the main body, wherein the upper base “a” and the lower base “b” satisfy the relation of “b>a” in their widths, and the angle θ between the lower base “b” and the side surface wall of the main body is set to be smaller than 90 degrees.

2. A resist pattern as defined in claim 1, wherein the angle θ is set to be 60 degrees or over.

3. A resist pattern as defined in claim 1 or 2, wherein the angle θ is set to 87 degrees or below.

4. A method for fabricating a resist pattern including a main body and a supplemental body to support the main body which is narrowed as compared with the main body, comprising the steps of:
forming a photoresist layer on a given base material, and
exposing the photoresist layer so that the focal point of the exposing light is shifted from on the surface of the resist layer.

5. A fabricating method as defined in claim 4, wherein in the exposing treatment for the photoresist layer, the focal point is set to a position above the photoresist layer.

6. A fabricating method as defined in claim 5, wherein the focal point is set to a position as high as 0.1-1.0 times of the thickness of the photoresist layer from on the surface of the photoresist layer.

7. A fabricating method as defined in any one of claims 4-6, further comprising the step of forming a polymethylglutarimide layer on the base material, wherein the photoresist layer is formed via the polymethylglutarimide layer on the base material.

8. A fabricating method as defined in any one of claims 4-6, wherein the photoresist layer is composed of a novolac type positive photoresist containing an additive phenol dissolution accelerator.

9. A method for fabricating a resist pattern including a main body and a supplemental body to support the main body which is narrowed as compared with the main body, comprising the steps of:
forming a photoresist layer on a given base material, and
exposing and developing the photoresist layer with a developing solution containing an interfacial active agent.

10. A fabricating method as defined in claim 9, wherein the concentration of the interfacial active agent in the developing solution is set to 0.0001-0.01 wt %.

11. A fabricating method as defined in claim 9 or 10, further comprising the step of forming a polymethylglutarimide layer on the base material, wherein the photoresist layer is formed via the polymethylglutarimide layer on the base material.

12. A fabricating method as defined in claim 9 or 10, wherein the photoresist layer is composed of a novolac type positive photoresist containing an additive phenol dissolution accelerator.

13. A method for patterning a thin film using a resist pattern as defined in any one of claims 1-3.

14. A method for patterning a thin film, comprising the steps of:
forming a thin film to be milled on a given base material,
forming a polymethylglutarimide layer on the thin film to be milled,
forming a photoresist layer on the polymethylglutarimide layer,
exposing the photoresist layer via a given mask so that the focal point of the exposing light is shifted from on the surface of the photoresist layer,
developing the photoresist layer,
partially removing the polymethylglutarimide layer with an alkaline water solution, to form a resist pattern constructed of the photoresist layer as a top layer and the polymethylglutarimide layer as a bottom layer, and
milling the thin film to be milled via the resist pattern, to form a patterned thin film.

15. A method for patterning a thin film, comprising the steps of:
forming a thin film to be milled on a given base material,
forming a novolac type positive photoresist layer containing an additive phenol dissolution accelerator on the thin film to be milled,
exposing the novolac type positive photoresist layer via a given mask so that the focal point of the exposing light is shifted from on the surface of the photoresist layer,
developing the photoresist layer, to form a resist pattern, and
milling the thin film to be milled via the resist pattern, to form a patterned thin film.

16. A patterning method as defined in claim 14 or 15, wherein in the exposing treatment for the photoresist layer, the focal point is set to a position above the photoresist layer.

17. A patterning method as defined in claim 16, wherein the focal point is set to a position as high as 0.1-1.0 times of the thickness of the photoresist layer from on the surface of the photoresist layer.

18. A method for patterning a thin film, comprising the steps of:
forming a thin film to be milled on a given base material,
forming a polymethylglutarimide layer on the thin film to be milled,
forming a photoresist layer on the polymethylglutarimide layer,
exposing the photoresist layer via a given mask,
developing the photoresist layer with a developing solution containing an interfacial active agent,
partially removing the polymethylglutarimide layer with an alkaline water solution, to form a resist pattern constructed of the photoresist layer as a top layer and the polymethylglutarimide layer as a bottom layer, and
milling the thin film to be milled via the resist pattern, to form a patterned thin film.

19. A method for patterning a thin film, comprising the steps of:
forming a thin film to be milled on a given base material,
forming a novolac type positive photoresist layer containing an additive phenol dissolution accelerator on the thin film to be milled,
exposing the novolac type positive photoresist layer via a given mask,
developing the photoresist layer with a developing solution containing an interfacial active agent, to form a resist pattern, and
milling the thin film to be milled via the resist pattern, to form a patterned thin film.

20. A patterning method as defined in claim 18 or 19, wherein the concentration of the interfacial active agent in the developing solution is set to 0.0001-0.01 wt %.

21. A method for patterning a thin film, comprising the steps of:
forming a polymethylglutarimide layer on a given base material,
forming a photoresist layer on the polymethylglutarimide layer,
exposing the photoresist layer via a given mask so that the focal point of the exposing light is shifted from on the surface of the photoresist layer,
developing the photoresist layer,
partially removing the polymethylglutarimide layer with an alkaline water solution, to form a resist pattern constructed of the photoresist layer as a top layer and the polymethylglutarimide layer as a bottom layer,
forming a thin film to be patterned on the base material so as to cover the resist pattern, and
lifting-off the resist pattern, to form a patterned thin film.

22. A method for patterning a thin film, comprising the steps of:
forming a novolac type positive photoresist layer containing an additive phenol dissolution accelerator on a given base material,
exposing the novolac type positive photoresist layer via a given mask so that the focal point of the exposing light is shifted from on the surface of the photoresist layer,
developing the photoresist layer, to form a resist pattern,
forming a thin film to be patterned on the base material so as to cover the resist pattern, and
lifting-off the resist pattern, to form a patterned thin film.

23. A patterning method as defined in claim 21 or 22, wherein in the exposing treatment for the photoresist layer, the focal point is set to a position above the photoresist layer.

24. A patterning method as defined in claim 23, wherein the focal point is set to a position as high as 0.1-1.0 times of the thickness of the photoresist layer from on the surface of the photoresist layer.

25. A method for patterning a thin film, comprising the steps of:
forming a polymethylglutarimide layer on a given base material,
forming a photoresist layer on the polymethylglutarimide layer,
exposing the photoresist layer via a given mask,
developing the photoresist layer with a developing solution containing an interfacial active agent,
partially removing the polymethylglutarimide layer with an alkaline water solution, to form a resist pattern constructed of the photoresist layer as a top layer and the polymethylglutarimide layer as a bottom layer,
forming a thin film to be patterned on the base material so as to cover the resist pattern, and
lifting-off the resist pattern, to form a patterned thin film.

26. A method for patterning a thin film, comprising the steps of:
forming a novolac type positive photoresist layer containing an additive phenol dissolution accelerator on a given base material,
exposing the novolac type positive photoresist layer via a given mask,
developing the photoresist layer with a developing solution containing an interfacial active agent, to form a resist pattern,
forming a thin film to be patterned on the base material so as to cover the resist pattern, and
lifting-off the resist pattern, to form a patterned thin film.

27. A patterning method as defined in claim 25 or 26, wherein the concentration of the interfacial active agent in the developing solution is set to 0.0001-0.01 wt %.

28. A method for patterning a thin film, comprising the steps of:
forming a thin film to be milled on a given base material,
forming a polymethylglutarimide layer on the thin film to be milled,
forming a photoresist layer on the polymethylglutarimide layer,
exposing the photoresist layer via a given mask so that the focal point of the exposing light is shifted from on the surface of the photoresist layer,
developing the photoresist layer,
partially removing the polymethylglutarimide layer with an alkaline water solution, to form a resist pattern constructed of the photoresist layer as a top layer and the polymethylglutarimide layer as a bottom layer,
milling the thin film to be milled via the resist pattern, to form a pre-patterned thin film,
forming a thin film to be patterned on the base material so as to cover the resist pattern, and
lifting-off the resist pattern, to form a patterned thin film including the pre-patterned thin film.

29. A method for patterning a thin film, comprising the steps of:
forming a thin film to be milled on a given base material,
forming a novolac type positive photoresist layer containing an additive phenol dissolution accelerator on the thin film to be milled,
exposing the novolac type positive photoresist layer via a given mask so that the focal point of the exposing light is shifted from on the surface of the photoresist layer,
developing the photoresist layer, to form a resist pattern,
milling the thin film to be milled via the resist pattern, to form a patterned thin film,
forming a thin film to be patterned on the base material so as to cover the resist pattern, and
lifting-off the resist pattern, to form a patterned thin film including the pre-patterned thin film.

30. A patterning method as defined in claim 28 or 29, wherein in the exposing treatment for the photoresist layer, the focal point is set to a position above the photoresist layer.

31. A patterning method as defined in claim 30, wherein the focal point is set to a position as high as 0.1-1.0 times of the thickness of the photoresist layer from on the surface of the photoresist layer.

32. A method for patterning a thin film, comprising the steps of:
forming a thin film to be milled on a given base material,
forming a polymethylglutarimide layer on the thin film to be milled,
forming a photoresist layer on the polymethylglutarimide layer,
exposing the photoresist layer via a given mask,
developing the photoresist layer with a developing solution containing an interfacial active agent,
partially removing the polymethylglutarimide layer with an alkaline water solution, to form a resist pattern constructed of the photoresist layer as a top layer and the polymethylglutarimide layer as a bottom layer,
milling the thin film to be milled via the resist pattern, to form a pre-patterned thin film,
forming a thin film to be patterned on the base material so as to cover the resist pattern, and
lifting-off the resist pattern, to form a patterned thin film including the pre-patterned thin film.

33. A method for patterning a thin film, comprising the steps of:
forming a thin film to be milled on a given base material,
forming a novolac type positive photoresist layer containing an additive phenol dissolution accelerator on the thin film to be milled,
exposing the novolac type positive photoresist layer via a given mask,
developing the photoresist layer with a developing solution containing an interfacial active agent, to form a resist pattern,
milling the thin film to be milled via the resist pattern, to form a pre-patterned thin film,
forming a thin film to be patterned on the base material so as to cover the resist pattern, and
lifting-off the resist pattern, to form a patterned thin film including the pre-resist pattern.

34. A patterning method as defined in claim 32 or 33, wherein the concentration of the interfacial active agent in the developing solution is set to 0.0001-0.01 wt %.

35. A method for manufacturing a micro device using a thin film-patterning method as defined in any one of claims 13-34.

36. A manufacturing method as defined in claim 35, wherein the micro device is a thin film magnetic head.

37. A manufacturing method as defined in claim 36, wherein the magnetoresistive effective type thin film element of the thin film magnetic head is manufactured by the patterning method as defined in any one of claims 13-34.
